(19) United States
(12) Patent Application Publication
(10) Pub. No.: US 2019/0287793 A1
(43) Pub. Date: Sep. 19, 2019

(54) System and Method for Tuning Thickness of Resist Films

(71) Applicant: Tokyo Electron Limited, Tokyo (JP)

(72) Inventors: Anton J. deVilliers, Clifton Park, NY (US); Jeffrey Smith, Albany, NY (US); Daniel Fulford, Albany, NY (US)

(21) Appl. No.: 16/357,648

(22) Filed: Mar. 19, 2019

Related U.S. Application Data
(60) Provisional application No. 62/645,113, filed on Mar. 19, 2018.

(51) Int. Cl. H01L 21/027; G03F 7/16; H01L 21/02

(52) U.S. Cl. CPC H01L 21/0273; H01L 21/02282; G03F 7/16

(57) ABSTRACT

Techniques herein include methods of tuning film thickness of a dispensed resist or solvent. Techniques herein include controlling a final thickness of a resist film by manipulating substrate spin speed, viscosity of photoresist, amount of solids within a photoresist, and solvent evaporation rates in real time from a dispense module. This includes mixing a higher-concentration photoresist with a dilution fluid proximate to a dispense nozzle just before deposition on a substrate. An amount of dilution fluid added can be calculated to result in a photoresist concentration or viscosity to result in a film of a desired thickness.

### CROSS REFERENCE TO RELATED APPLICATIONS

The present application claims the benefit of U.S. Provisional Patent application No. 62/645,113, filed on Mar. 19, 2018, entitled “System and Method for Tuning Thickness of Resist Films,” which is incorporated herein by reference in its entirety.

### BACKGROUND OF THE INVENTION

The present disclosure relates to semiconductor manufacturing and particularly to dispensing materials on a substrate.

Semiconductor manufacturing includes several processing steps that involve depositing liquid on a substrate. These processing steps include, among others, coating a wafer, developing a latent pattern, etching material on a wafer, and cleaning/rinsing a wafer.

In a routine fabrication process, a thin layer of light-sensitive material, such as photoresist, is coated on a working surface or upper surface of a substrate. This photoresist layer is subsequently patterned via photolithography to define a latent pattern in the photoresist. This latent pattern is formed into an etch mask for transferring the pattern into an underlying layer. The patterning of the light-sensitive material generally involves coating a working surface of the substrate with a thin film of light-sensitive material, exposing the thin film of light-sensitive material to a radiation source through a reticle (and associated optics) using, for example, a micro-lithography system, followed by a developing process during which the removal of the irradiated regions of the light-sensitive material occurs (or non-irradiated regions depending on a tone of photoresist and tone developer used) using a developing solvent.

During the coating process, a substrate is positioned on a substrate holder, and is rotated at high speed, i.e., several thousand or tens of thousands of revolutions per minute (rpm), while resist solution is dispensed on an upper surface of the substrate. When, the resist solution is dispensed at the center of the substrate, the resist solution spreads radially across the substrate due to centrifugal forces imposed by the substrate rotation. Wet etch and cleaning processes can be similarly executed. In a development process, a solvent developer is deposited on a substrate that is rotated at a high speed. The solvent developer dissolves soluble portions of the photoresist, and then developer and dissolved photoresist are removed radially across the substrate due to centrifugal forces. Wet etch processes, cleaning process, and rinsing processes are executed similarly to a development process in that a liquid is deposited on a rotating wafer and removed by centrifugal forces to clear or clean off a particular material or residue.

### SUMMARY

Depositing photoresist (coating) and dispensing developer (developing) on a semiconductor substrate are routine processes within semiconductor manufacturing to create a completed chip. Photoresist films are typically added to a wafer or substrate using a coater-developer tool known in the semiconductor industry as a Track tool. A coater-developer tool manages substrates within an environmentally controlled enclosure and among various modules. Some modules can be used for dispensing, others for baking, and others for developing. A dispense module can be used to dispense or spray resist from a nozzle onto wafers and spins the wafers causing dispensed resist to coat the wafer. A final thickness of a given photoresist film deposited on a wafer can be a function of substrate spin speed, viscosity of dispensed photoresist, amount of solids within dispensed photoresist, solvent evaporation rate, and initial film height. Using a technique similar to dispense, with development, developing chemicals are dispensed via a nozzle onto a spinning wafer. Soluble material is then dissolved or taken into the liquid develop and then cast from the wafer as the wafer spins within an enclosure or module.

Techniques herein include methods and systems of tuning film thickness of a dispensed resist. This includes controlling a resulting film thickness of any photoresist by controlling spin speed, viscosity of photoresist, amount of solid proprietary resist, solvent evaporation rate, and initial film height. These parameters are controlled in real time via a control panel. Systems herein can provide real time feedback to the system users and provide automated processes. Feedback can be used for adjusting dispense operation parameters in real time and/or for predicting a final film thickness. Additionally, methods can include receiving an input of a desired film thickness and a dispensed photoresist can be mixed with a dilution fluid to result in the desired film thickness. Methods can include tuning dilutions of developer or photoresist on a track tool immediately before dispense operations.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 is a cross-sectional schematic view of an example dispense system according to embodiments herein.

### DETAILED DESCRIPTION

Techniques herein include methods and systems of tuning film thickness of a dispensed resist. Techniques herein include controlling a final thickness of a resist film by manipulating substrate spin speed, viscosity of photoresist, amount of solids within a photoresist, and solvent evaporation rates in real time from a dispense module. This includes mixing a higher-concentration photoresist with a dilution fluid proximate to a dispense nozzle just before deposition on a substrate.

A given photoresist typical contains a proprietary resist solid diluted into a solvent or diluted with a solvent. Many variations of photoresist can be purchased from a given chemical supplier at various dilutions. By starting with a higher concentration of photoresist solids per solvent, this photoresist can be diluted using techniques herein to any concentration of photoresist, in real time. As more solvent or other dilution fluid is added to the photoresist the viscosity decreases changing the final thickness of the film. Due to the unique nature of photoresist only certain solvents can be mixed into the photoresist to dilute the photoresist without damaging its integrity. The solvents that can be used to dilute the photoresist should generally be—but not limited to—the same as what the solid resist is stored in. A mixture of solvents can also be added in place of a single solvent. The amount of different solvents can be controlled to change the viscosity and evaporation rate of the photoresist changing the final thickness. The final thickness can be fine-tuned real time based on the viscosity of the final photoresist mixture by real time manipulation of multiple solvents diluted into a photoresist.

There are many solvents that can be used with techniques herein. Example solvents include: GBL (gamma-butyrolactone), PGME (propylene glycol methyl ether), PGMEA (propylene glycol methyl ether acetate), cyclohexanone, acetone, methanol, 2-propanol (IPA), N-butyl acetate, MiBK (methyl isobutyl ketone), and NM.

Techniques herein can be applied to developer dispenses similar to photoresist dispenses. Developers contain solvents and in some cases proprietary chemistries. The same or different solvent tanks can be mixed in the same or separate chambers as the photoresist solvent tanks or chambers herein. Adding stronger solvent to a developer will increase the development power just as adding weaker solvent will decrease the development power. Real time tuning on the developer allows more than one dilution of developer to be used on one tool at a time giving real time updates to a tool user.

Multiple dilutions of the same resist can be run on the same developer-coater system with no extra resist requirement. This allows more space inside tools and more flexibility in the number of resists and dilutions that can be used in one tool. Instead of halving multiple dilutions of the same resist loaded onto one machine there can be multiple resists with a real time concentration adjustment.

One embodiment includes a method of depositing photoresist on a substrate. The method can include identifying a specified film thickness to be deposited on a substrate. This can be essentially a vertical height of the film thickness desired for a given substrate stack. A supply of photoresist fluid is accessed. The photoresist fluid has an initial concentration of photoresist solids within a solvent. This initial concentration can be highly concentrated or above an upper concentration of a given photoresist film with relatively greater thickness or solids concentration. A supply of a dilution fluid is then accessed. The dilution fluid is mixed with the photoresist fluid within a mixing chamber proximate to a dispense nozzle resulting in a diluted photoresist fluid having a resulting concentration of photoresist solids that is less than the initial concentration of photoresist solids. The two fluids can essentially be mixed near a dispense nozzle or dispense chamber, and mixed just before being dispensed. The diluted photoresist fluid is then dispensed onto a working surface of the substrate via the dispense nozzle while the substrate is rotating.

Methods herein can include calculating an amount of dilution fluid to mix with the photoresist fluid to result in the diluted photoresist dispensed forming a photoresist film having the specified film thickness. In other words, enough solvent or sufficient solvent is added to the concentrated photoresist to result is a desired film thickness. Spin speed of the substrate can be adjusted to result in a deposited photoresist film having the specified film thickness. A final film thickness can be a function of both photoresist thickness and substrate spin speed, so both can be controlled to result in a desired thickness. The amount of dilution fluid added is based on film thickness measurements from prior film depositions and dilution amounts.

The amount of dilution fluid added can be based on real time feedback of photoresist film progression across the substrate. For example, real time feedback of photoresist film progression can be obtained by analysis of stroboscopic images of the surface of the substrate.

Mixing the dilution fluid with the photoresist fluid can occur at a time of dispensing the diluted photoresist fluid onto the substrate. For example, fluids can be mixed immediately before dispensing, seconds before dispensing, or even minutes before dispensing. Methods can include identifying physical properties of the working surface of the substrate and then an amount of dilution fluid added to the photoresist fluid is based on the physical properties of the working surface of the substrate. For example, a substrate roughness from a given anti-reflective coating or nanostructure pattern can be used.

Methods can include calculating an amount of dilution fluid to mix with the photoresist fluid to result in the diluted photoresist having a predetermined concentration of photoresist solids. The dilution fluid can be mixed with the photoresist fluid within a mixing module having a photoresist fluid inlet and a dilution fluid inlet. An amount of dilution fluid added to the photoresist fluid can be increased in response to identifying a diluted photoresist fluid having a measured viscosity that is above a predetermined value. A viscosity can be measured at a nozzle or on the substrate surface. An amount of dilution fluid added to the photoresist fluid can be increased in response to identifying a diluted photoresist fluid having a progression rate across a working surface of the substrate that is less than a predetermined film progression rate. This can be identified using a stroboscope system. Identifying the specified film thickness can include receiving user input that indicates a specific film thickness to be deposited on the substrate.

Other methods can include monitoring an evaporation rate of solvent from the diluted photoresist fluid during progression across the substrate. In response to identifying an evaporation rate that exceeds a predetermined threshold, an amount of dilution fluid added to the photoresist fluid can be adjusted. An evaporation rate of solvent from the diluted photoresist fluid can be monitored during progression across the substrate. In response to identifying an evaporation rate that exceeds a predetermined threshold, a spin speed of the substrate can be adjusted.

In another embodiment, a supply of photoresist fluid is accessed. The photoresist fluid has an initial viscosity. A supply of a dilution fluid is accessed or otherwise received. The dilution fluid is mixed with the photoresist fluid within a mixing chamber proximate to a dispense nozzle resulting in a diluted photoresist fluid having a resulting viscosity that is less viscous than the initial viscosity. The diluted photoresist is dispensed onto a working surface of the substrate via the dispense nozzle while the substrate is rotating.

Another embodiment includes a method of dispensing developer on a substrate. A photoresist film to be developed is provided or otherwise received. The photoresist film is or has been deposited on a working surface of a substrate. A specified concentration of developer to be dispensed on a substrate is identified. A supply of developer fluid is accessed. The developer fluid has an initial developer concentration. A dilution fluid is mixed with the developer fluid within a mixing chamber proximate to a dispense nozzle resulting in a diluted developer fluid having a resulting concentration that is less than the initial concentration. The diluted developer fluid is dispensed onto the photoresist film via the dispense nozzle while the substrate is rotating.

This method can include calculating an amount of dilution fluid to mix with the developer fluid based on a film thickness of the photoresist film. A spin speed of the substrate can be adjusted based on an amount of dilution fluid added to the developer fluid. An evaporation rate of solvent can be monitored from the substrate during a development of the photoresist film. In response to identifying an evaporation rate that exceeds a predetermined threshold, an amount of dilution fluid added to the photoresist fluid can be adjusted.

As can be appreciated, in addition to film thickness tuning, techniques herein provide many additional benefits as well as enabling other methods and materials. For example, mixing at the point of dispense mitigates shelf life concerns of pre-mixed or pre-diluted resist. Benefits can include shot size reduction, pH shock mitigation, developer defectivity improvement, coater defectivity improvement, source mask resist patterning optimization, and ultimate resist reduction consumption. Blending herein can include adjusting a concentration or loading level of a photo acid generator (PAG) or a photo destructive base (PDB).

Another embodiment herein is dispensing epoxy materials on a semiconductor wafer. Epoxy products include cured epoxy resins. Conventional applications for epoxy resins are adhesives, coatings, and composite resins. For such applications, an epoxy resin is mixed with a hardener. After mixing, there is a limited amount of time that the mixture remains liquid before becoming cured. This time limit depends on a given epoxy resin and selected hardener. Curing can happen in 5 minutes or up to 90 minutes or more. As can be appreciated, such mixtures cannot be mixed together by a manufacturers and shipped and stored for later use. While long term storage of photoresist mixtures typically results in increased defectivity, long term storage of mixed epoxy resins means an entirely unusable mixture after 30-120 minutes, typically. With methods herein, however, epoxy resins can be deposited on semiconductor wafers because the epoxy resin and curing agent can be mixed at the point of deposition.

Conventional coater-developer tools can coat hundreds of wafers per hour, using bake modules to accelerate curing. This means that a given epoxy resin and curing agent can be mixed proximate a dispense nozzle and coated on many wafers before hardening prevents continued coating. Coating can continue without pause because of mixing at the source of deposition. As a given epoxy is mixed with a given curing agent, this mixture is dispensed making room to mix more epoxy resin. In other words, recently mixed resin is pushed out of the dispense system by newly mixed resin. This enables prolonged use for deposition of epoxy resins on substrates. If needed depending on properties of a given epoxy resin, a corresponding dispense system can be cleaned out of epoxy mixture at given intervals to prevent buildup of the epoxy resin within mixing and dispense conduits. Being able to dispense epoxy coatings onto a substrate provides more fabrication options and materials. For example, epoxy materials can provide mechanical, thermal or chemical properties for inclusion in a given integration or packaging flow. A given epoxy can have an etch resistivity different than other materials to enable more etch options.

One example embodiment includes a method of depositing epoxy materials on a substrate, such as by using a coater-developer tool. A semiconductor wafer to be processed is accessed, such as by placing a wafer on a chuck within a coating module of a Track tool. A supply of epoxy resin fluid is accessed, such as by using a first fluid delivery conduit and pump assembly. A supply of an epoxy resin curing agent (hardener or cross-linker) is accessed using a second delivery conduit. These separate delivery conduits converge at a mixing chamber located proximate to a dispense nozzle. A predetermined amount of the epoxy resin curing agent is then mixed with the epoxy resin fluid within the mixing chamber resulting in a mixed epoxy resin fluid. This mixed epoxy resin fluid is then dispensed onto a working surface of the semiconductor substrate via the dispense nozzle while the substrate is rotating. After dispense and spin coat for full coverage, the epoxy resin film completes curing (with or without baking), and then subsequent fabrication steps can continue.

Epoxy resins and curing agents themselves are conventionally known, and so various amines, acids, phenols, alcohols, thiols and other agents can be selected for a given application as a curing agent. Likewise there are various polymers that can be selected for use as an epoxy resin depending on desired properties.

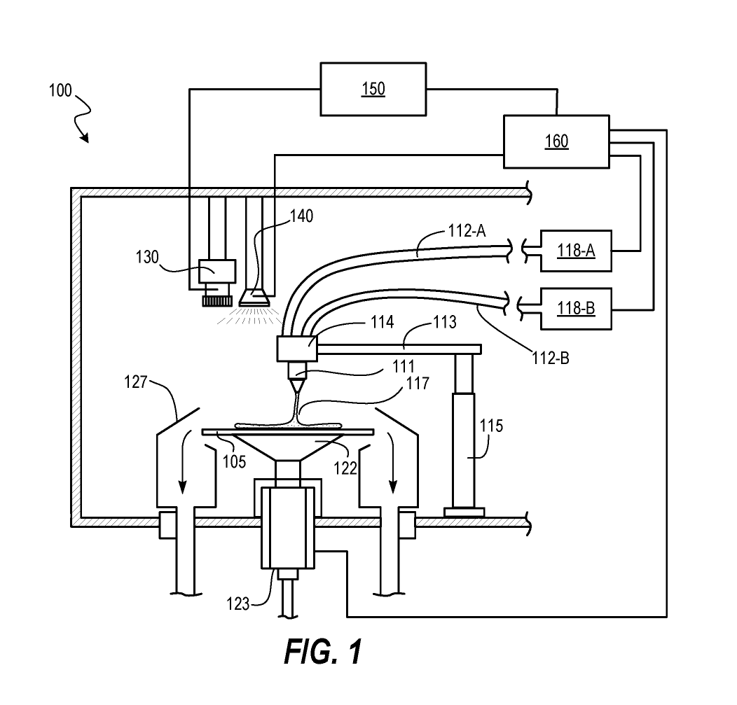

Referring now to FIG. 1, a cross-sectional schematic is illustrated showing an example apparatus for executing methods described herein. System 100 is a system for dispensing liquid on a substrate 105. Substrate holder 122 is configured to hold substrate 105 and rotate substrate 105 about an axis. Motor 123 can be used to rotate the substrate holder 122 at a selectable rotational velocity. A dispense unit 118-A and 118-B is configured to dispense liquid on a working surface of the substrate 105 while the substrate 105 is being rotated by the substrate holder 122. Dispense units 118-A and 118-B can be positioned directly over a substrate holder, or can be positioned at another location. If positioned away from the substrate holder, than conduits 112-A and 112-B can be used to deliver fluid to mixing chamber 114. Mixed fluid can exit through nozzle 111. FIG. 1 illustrates mixed fluid 117 (diluted fluid) being dispensed onto a working surface of substrate 105. Collection system 127 can then be used to catch or collect excess mixed fluid 117 that spins off substrate 105 during a given dispense operation.

Dispense components can include nozzle arm 113 as well as support member 115, which can be used to move a position of nozzle 111 across the substrate 105, or to be moved away from the substrate holder 122 to a resting location, such as for rest upon completion of dispense operations. Dispense unit 118-A and 118-B can have one or more valves in communication with system controller 160. Image capturing device 130 can include a single camera or multiple cameras. Stroboscope 140 can be used to make the substrate appear slow moving or stationary to better see liquid progression across the substrate. Processor 150 can collect captured images for analysis and transmit data and/or instructions to system controller 160

The dispense units 118-A and 118-B can have various embodiments configured to control dispense of a selectable volume of fluid on a substrate. For example, dispense unit 118-A can have access to a supply of photoresist. Such photoresist supply can be a concentrated form of a given photoresist. Dispense unit 118-B can have access to a supply of a particular solvent that can be used to dilute the given photoresist. Dispense unit 118-A can deliver a specific amount of photoresist to mixing chamber 114, while dispense unit 118-B delivers a specific amount of a corresponding solvent to the mixing chamber 114. The photoresist and solvent are then mixed within mixing chamber 114 resulting in a diluted fluid which is then deposited on substrate 105. The diluted fluid can have a particular viscosity and/or concentration that results in a desired film thickness when spun at a particular speed. Accordingly, thicknesses of resist films can be tuned at a time of dispense.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of depositing photoresist on a substrate, the method comprising:
identifying a specified film thickness of photoresist to be deposited on a substrate;
accessing a supply of a photoresist fluid, the photoresist fluid having an initial concentration of photoresist solids within a solvent;
accessing a supply of a dilution fluid;
mixing a predetermined amount of the dilution fluid with the photoresist fluid within a mixing chamber located proximate to a dispense nozzle resulting in a diluted photoresist fluid having a resulting concentration of photoresist solids that is less than the initial concentration of photoresist solids; and
dispensing the diluted photoresist fluid onto a working surface of the substrate via the dispense nozzle while the substrate is rotating.

2. The method of claim 1, further comprising calculating the predetermined amount of the dilution fluid to mix with the photoresist fluid to result in the diluted photoresist fluid dispensed forming a photoresist film having the specified film thickness.

3. The method of claim 2, further comprising adjusting spin speed of the substrate to result in the diluted photoresist fluid dispensed on the substrate forming the photoresist film having the specified film thickness.

4. The method of claim 2, wherein mixing the predetermined amount of the dilution fluid with the photoresist fluid occurs at a time of dispensing the diluted photoresist fluid onto the substrate.

5. The method of claim 1, wherein mixing the predetermined amount of the dilution fluid with the photoresist fluid adds a sufficient amount of dilution fluid to result in a deposited photoresist film having the specified film thickness.

6. The method of claim 5, wherein the predetermined amount of the dilution fluid is based on film thickness measurements from prior film depositions and dilution amounts.

7. The method of claim 5, wherein the predetermined amount of the dilution fluid is based in part on real time feedback of photoresist film progression across the substrate.

8. The method of claim 7, wherein the real time feedback of photoresist film progression is obtained by analysis of stroboscopic images of the surface of the substrate.

9. The method of claim 1, further comprising identifying physical properties of the working surface of the substrate, wherein the predetermined amount of the dilution fluid added to the photoresist fluid is based on the physical properties of the working surface of the substrate.

10. The method of claim 1, further comprising calculating the predetermined amount of the dilution fluid to result in the diluted photoresist fluid having a predetermined concentration of photoresist solids.

11. The method of claim 1, wherein the predetermined amount of the dilution fluid is mixed with the photoresist fluid within a mixing module having a photoresist fluid inlet and a dilution fluid inlet.

12. The method of claim 1, further comprising:
increasing an amount of dilution fluid added to the photoresist fluid in response to identifying the diluted photoresist fluid having a measured viscosity that is above a predetermined value.

13. The method of claim 1, further comprising:
increasing an amount of dilution fluid added to the photoresist fluid in response to identifying the diluted photoresist fluid having a progression rate across the working surface of the substrate that is less than a predetermined film progression rate.

14. The method of claim 1, wherein identifying the specified film thickness includes receiving user input that indicates the specified film thickness to be deposited on the substrate.

15. The method of claim 1, further comprising:
monitoring an evaporation rate of solvent from the diluted photoresist fluid during progression across the substrate; and
in response to identifying an evaporation rate that exceeds a predetermined threshold rate of evaporation, adjusting an amount of dilution fluid added to the photoresist fluid.

16. The method of claim 1, further comprising:
monitoring an evaporation rate of solvent from the diluted photoresist fluid during progression across the substrate; and
in response to identifying an evaporation rate that exceeds a predetermined threshold rate of evaporation, adjusting a spin speed of the substrate.

17. A method of depositing photoresist on a substrate, the method comprising:
accessing a supply of a photoresist fluid, the photoresist fluid having an initial viscosity;
accessing a supply of a dilution fluid;
mixing a predetermined amount of the dilution fluid with the photoresist fluid within a mixing chamber positioned proximate to a dispense nozzle resulting in a diluted photoresist fluid having a resulting viscosity that is less viscous than the initial viscosity; and
dispensing the diluted photoresist fluid onto a working surface of the substrate via the dispense nozzle while the substrate is rotating, the predetermined amount of the dilution fluid selected to result in the diluted photoresist fluid dispensed forming a photoresist film having the specified film thickness.

18. A method of dispensing developer on a substrate, the method comprising:
providing a photoresist film to be developed, the photoresist film having been deposited on a working surface of a substrate, the photoresist film having a latent pattern in which portions of the photoresist film are soluble to a specific developer;
identifying a predetermined concentration of developer to be dispensed on the substrate;
accessing a supply of a developer fluid, the developer fluid having an initial developer concentration;
mixing a predetermined amount of dilution fluid with the developer fluid within a mixing chamber positioned proximate to a dispense nozzle resulting in a diluted developer fluid having a resulting developer concentration that is less than the initial developer concentration;
dispensing the diluted developer fluid onto the photoresist film via the dispense nozzle while the substrate is rotating.

19. The method of claim 18, further comprising:
calculating the predetermined amount of dilution fluid to mix with the developer fluid based on a film thickness of the photoresist film; and
adjusting spin speed of the substrate based on the predetermined amount of dilution fluid added to the developer fluid.

20. The method of claim 19, further comprising:
monitoring an evaporation rate of solvent from the substrate during a development of the photoresist film; and
in response to identifying an evaporation rate that exceeds a predetermined threshold rate of evaporation, adjusting an amount of dilution fluid added to the developer fluid.
